(19) United States
(12) Patent Application Publication
(10) Pub. No.: US 2026/0339877 A1
(43) Pub. Date: Oct. 29, 2026

(54) ADDRESS DETERMINATION CIRCUIT AND SEMICONDUCTOR DEVICE

(71) Applicant: ABLIC Inc., Nagano (JP)

(72) Inventor: Biao SHEN, Nagano (JP)

(73) Assignee: ABLIC Inc., Nagano (JP)

(21) Appl. No.: 19/575,911

(22) Filed: Mar. 23, 2026

(30) Foreign Application Priority Data
Mar. 31, 2025 (JP) 2025-059187
Mar. 19, 2026 (JP) 2026-046229

(51) Int. Cl. G06F 13/42; H03K 19/20

(52) U.S. Cl. CPC G06F 13/4282; H03K 19/20

(57) ABSTRACT

Provided are an address determination circuit and a semiconductor device that improve accuracy of address determination with a simple circuit configuration. An address selection signal determination circuit receives a first determination signal based on a latched level of a serial data signal at first and second edge timings of an address selection signal, and a second determination signal based on a latched level of a serial clock signal at the first and second edge timings. The determination circuit determines the address selection signal is the serial clock signal in a case in which the first determination signal indicates false, determines the address selection signal is the serial data signal in a case in which the second determination signal indicates false, and determines the address selection signal is a power supply voltage based on its voltage in a case in which both determination signals indicate true.

### CROSS-REFERENCE TO RELATED APPLICATIONS

This application is based on and claims priority under 35USC 119 from Japanese Patent Application No. 2025-59187 filed Mar. 31, 2025 and No. 2026-046229 filed Mar. 19, 2026.

### TECHNICAL FIELD

The present invention relates to an address determination circuit and a semiconductor device.

### BACKGROUND ART

A plurality of modules inside and outside a computer are sometimes used by being connected to a common path for exchanging data (bus connection). In such bus connection, an individual address is set for each module, and a command including the address of a slave which is a controlled module is transmitted from a master which is a control module. On the slave side, the received controlled address is compared with a set own address, and a response is made only to a command of a matching controlled address.

In recent years, communication systems sometimes use an inter-integrated circuit (I²C) serial transfer bus including two signal lines for a serial data signal (SDA signal) and a serial clock signal (SCL signal) in accordance with communication protocols.

In a case in which a plurality of modules functioning as slaves for I²C communication or the like are desired to be used, addresses are required to be individually set. As a method of allowing a user to easily set the addresses, there is used a method involving individually providing an address input terminal (SA terminal) and selecting an address depending on an input level of the address input terminal. A method of detecting binary values using the SA terminal as digital input is the simplest. However, it is difficult to dedicate a large number of terminals exclusively for address input in a product frequently using a package with a small number of terminals, because the number of SA terminals is required to be increased to connect a larger number of modules to a communication bus.

Thus, various technologies capable of setting an address of a slave module with a simple circuit configuration have been studied from the viewpoint of making a module connected to a bus applicable to a package with a small number of terminals (see, for example, Japanese Patent Application Laid-open No. 2010-212989). In the related-art address determination circuit and the related-art semiconductor device as described in Japanese Patent Application Laid-open No. 2010-212989, an address is sometimes erroneously determined, leaving room for improvement. At least one aspect of the present invention has an object to provide an address determination circuit and a semiconductor device that improve accuracy of address determination with a simple circuit configuration.

### SUMMARY OF INVENTION

According to at least one aspect of the present invention, there is provided an address determination circuit which is a circuit configured to determine an address of serial communication that transmits and receives a transmission start signal, a data signal, and a transmission end signal through a communication line, the address determination circuit including: an address selection signal input terminal; a serial data input terminal; a serial clock input terminal; and an address selection signal determination circuit configured to: receive a first determination signal based on a result of latching a level of a serial data signal supplied to the serial data input terminal at a first edge timing at which an address selection signal supplied to the address selection signal input terminal transitions from a first power supply voltage to a second power supply voltage, and at a second edge timing at which the address selection signal transitions from the second power supply voltage to the first power supply voltage; and receive a second determination signal based on a result of latching a level of a serial clock signal supplied to the serial clock input terminal at the first edge timing and at the second edge timing, in which the address selection signal determination circuit is configured to: determine that the address selection signal is the serial clock signal in a case in which the first determination signal is at a signal level corresponding to false; determine that the address selection signal is the serial data signal in a case in which the second determination signal is at a signal level corresponding to false; and determine that the address selection signal is one of the first power supply voltage or the second power supply voltage based on a voltage of the address selection signal in a case in which both of the first determination signal and the second determination signal are at signal levels corresponding to true. According to the at least one aspect of the present invention, the accuracy of address determination can be improved with a simple circuit configuration.

### BRIEF DESCRIPTION OF DRAWINGS

FIG. 1 is a schematic diagram for illustrating a configuration example of an address determination circuit and a semiconductor device according to an embodiment of the present invention.

FIG. 2 is a circuit diagram for illustrating a configuration example of an SDA short-circuit determination signal generation circuit in the address determination circuit according to the embodiment.

FIG. 3 is a circuit diagram for illustrating a configuration example of an SCL short-circuit determination signal generation circuit in the address determination circuit according to the embodiment.

FIG. 4A is a timing chart in the address determination circuit according to the embodiment in a case in which an SA terminal is short-circuited to an SCL line.

FIG. 4B is a timing chart in the address determination circuit according to the embodiment in a case in which the SA terminal is short-circuited to an SDA line.

FIG. 5 is a truth value table for illustrating an operation of an SA terminal short-circuit determination circuit included in the address determination circuit according to the embodiment.

FIG. 6 is a schematic diagram for illustrating a configuration example of an address determination circuit according to a reference example.

FIG. 7A is a timing chart for illustrating a first example of erroneous address determination of the address determination circuit according to the reference example.

FIG. 7B is a timing chart for illustrating a second example of erroneous address determination of the address determination circuit according to the reference example.

FIG. 8 is a schematic diagram for illustrating a first modification example (second configuration example) of the address determination circuit and the semiconductor device according to the embodiment.

FIG. 9 is a circuit diagram for illustrating a first modification example (second configuration example) of the SDA short-circuit determination signal generation circuit in the address determination circuit according to the embodiment.

FIG. 10 is a circuit diagram for illustrating a first modification example (second configuration example) of the SCL short-circuit determination signal generation circuit in the address determination circuit according to the embodiment.

FIG. 11 is a circuit diagram for illustrating a second modification example (third configuration example) of the SDA short-circuit determination signal generation circuit in the address determination circuit according to the embodiment.

FIG. 12 is a schematic diagram for illustrating a second modification example (third configuration example) of the address determination circuit and the semiconductor device according to the embodiment.

FIG. 13 is a circuit diagram for illustrating a second modification example (third configuration example) of the SCL short-circuit determination signal generation circuit in the address determination circuit according to the embodiment.

FIG. 14 is a circuit diagram for illustrating a second modification example (third configuration example) of the SDA short-circuit determination signal generation circuit in the address determination circuit according to the embodiment.

FIG. 15 is a timing chart for illustrating a case in which the SA terminal is short-circuited to the SCL line in the address determination circuit according to the second modification example.

### DESCRIPTION OF EMBODIMENTS

An address determination circuit and a semiconductor device according to at least one embodiment of the present invention are described below with reference to the drawings. In the at least one embodiment, “high level” and “low level” in a bit signal are synonymous with “1” and “0” of the bit signal, respectively.

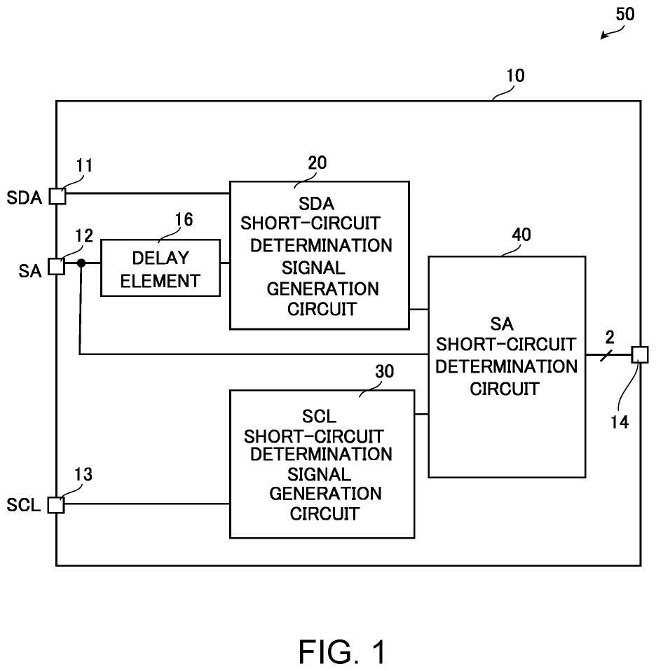

FIG. 1 is a schematic diagram for illustrating a configuration example of an address determination circuit 10 which s an example of the address determination circuit according to the embodiment and a semiconductor device 50 which is an example of the semiconductor device according to the embodiment.

The address determination circuit 10 is a circuit configured to determine an address of serial communication that transmits and receives a transmission start signal, a data signal, and a transmission end signal through a communication line. The address determination circuit 10 includes, for example: an SDA terminal 11; an SA terminal 12; an SCL terminal 13; an output terminal 14; a delay element 16 configured to delay a received signal by a predetermined time and provide the delayed signal; an SDA short-circuit determination signal generation circuit 20; an SCL short-circuit determination signal generation circuit 30; and an SA terminal short-circuit determination circuit 40.

The SDA terminal 11 serving as a serial data input terminal is connected to a serial data line (hereinafter referred to as “SDA line,” not illustrated) to which a serial data signal (hereinafter referred to as “SDA signal”) is supplied.

The SCL terminal 13 serving as a serial clock input terminal is connected to a serial clock line (hereinafter referred to as “SCL line,” not illustrated) to which a serial clock signal (hereinafter referred to as “SCL signal”) is supplied.

The SA terminal 12 serving as an address selection signal input terminal is a terminal to which address selection signals (hereinafter referred to as “SA signals”) for which four different addresses are set are supplied, and is selectively connected to four supply sources. Four locations which are connection destinations of the SA terminal 12, that is, counterparts short-circuited to the SA terminal 12, are the SDA line, the SCL line, a VSS line for supplying a voltage Vss as a first power supply voltage, and a VDD line for supplying a voltage Vdd as a second power supply voltage.

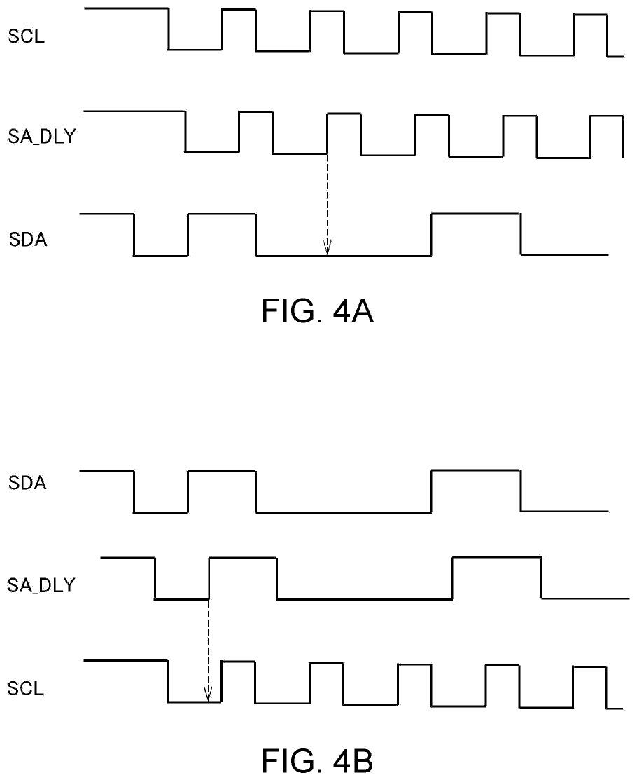

The SDA short-circuit determination signal generation circuit 20 is configured to generate a signal including a signal level corresponding to a result of determining a condition for determining that the short-circuit counterpart of the SA terminal 12 is not the SDA line, based on the SDA signal and a signal SA_DLY (see FIG. 4A and FIG. 4B) which is the SA signal delayed by a predetermined time. The SCL short-circuit determination signal generation circuit 30 is configured to generate a signal including a signal level corresponding to a result of determining a condition for determining that the short-circuit counterpart of the SA terminal 12 is not the SCL line, based on the SCL signal and the signal SA_DLY (see FIG. 4A and FIG. 4B).

The SA terminal short-circuit determination circuit 40 serving as an address selection signal determination circuit includes a first input node configured to receive an SDA short-circuit determination signal, a second input node configured to receive the SA signal, a third input node configured to receive an SCL short-circuit determination signal, and an output node configured to provide a 2-bit signal corresponding to the connection destination of the SA terminal 12.

The SA terminal short-circuit determination circuit 40 determines a counterpart to which the SA terminal 12 is short-circuited based on the SDA short-circuit determination signal, the SA signal, and the SCL short-circuit determination signal supplied to the first node to the third node, respectively, and provides a 2-bit signal corresponding to the determined short-circuit counterpart, that is, the connection destination. The 2-bit signal provided from the SA terminal short-circuit determination circuit 40 is supplied to the output terminal 14, and is supplied from the output terminal 14 to a subsequent circuit (not illustrated).

The principle of address determination of the address determination circuit 10 is described here. The address determination circuit 10 compares the SA signal supplied from the SA terminal 12 with the signal SA_DLY which is the SA signal delayed by a predetermined time from the viewpoint of ensuring a setup/hold time of an FF circuit. With a contrapositive of a proposition whose true or false is definite being determined between the address selection signal and the signal SA_DLY, it is determined that the address selection signal is not the SCL signal or not the SDA signal.

Specifically, in a case in which the SA signal is the SCL signal, the SCL signal is “1” at the rising edge of the signal SA_DLY, and the SCL signal is “0” at the falling edge of the signal SA_DLY. Similarly, in a case in which the address selection signal is the SDA signal, the SDA signal is “1” at the rising edge of the signal SA_DLY, and the SDA signal is “0” at the falling edge of the signal SA_DLY.

After all, it is clear that the following two propositions are both true:
First proposition “In a case in which the address selection signal is the SCL signal, the SCL signal is ‘1’ at the rising edge of the signal SA_DLY, and the SCL signal is ‘0’ at the falling edge of the signal SA_DLY.”; and
Second proposition “In a case in which the address selection signal is the SDA signal, the SDA signal is ‘1’ at the rising edge of the signal SA_DLY, and the SDA signal is ‘0’ at the falling edge of the signal SA_DLY.”

The address determination circuit 10 utilizes the fact that a third proposition which is a contrapositive of the first proposition and a fourth proposition which is a contrapositive of the second proposition are both true, to thereby determine that the address selection signal is not the SCL signal or not the SDA signal. The third proposition and the fourth proposition are as follows:
Third proposition “Unless the SCL signal is ‘1’ at the rising edge of the signal SA_DLY and the SCL signal is ‘0’ at the falling edge of the signal SA_DLY, the address selection signal is not the SCL signal.”; and
Fourth proposition “Unless the SDA signal is ‘1’ at the rising edge of the signal SA_DLY and the SDA signal is ‘0’ at the falling edge of the signal SA_DLY, the address selection signal is not the SDA signal.”

Subsequently, configuration examples of the SDA short-circuit determination signal generation circuit 20 serving as a first signal generation circuit and the SCL short-circuit determination signal generation circuit 30 serving as a second signal generation circuit are described.

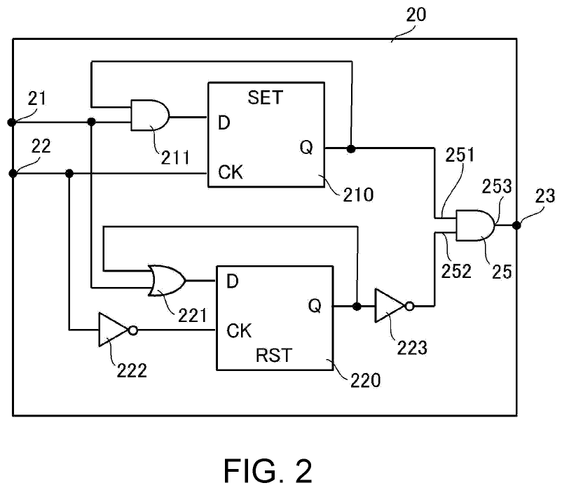

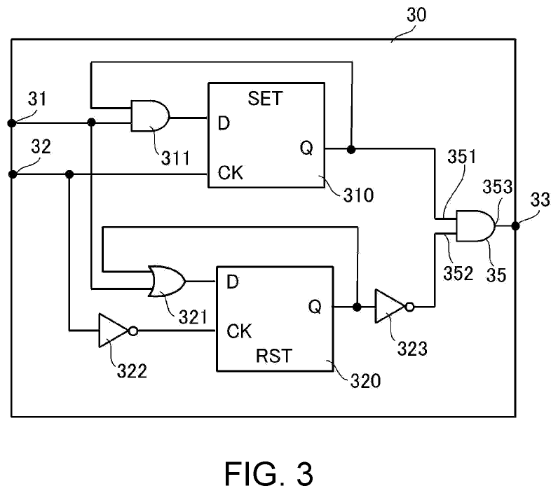

FIG. 2 and FIG. 3 are circuit diagrams for illustrating configuration examples of the SDA short-circuit determination signal generation circuit 20 and the SCL short-circuit determination signal generation circuit 30, respectively.

The SDA short-circuit determination signal generation circuit 20 includes, for example: a D flip-flop circuit (hereinafter referred to as “D-FF circuit”) 210 configured to operate at a clock rising edge of a clock signal and retain information until a next rising edge of the clock signal; an AND circuit 211; a D-FF circuit 220; an OR circuit 221; an inverter 222 and an inverter 223; and an AND circuit 25. The SDA short-circuit determination signal generation circuit 20 further includes: a first input node 21 connected to the SDA terminal 11; a second input node 22 connected to an output node of the delay element 16; and an output node 23 connected to an output terminal 253 of the AND circuit 25.

The AND circuit 211 includes a first input terminal connected to an output terminal Q of the D-FF circuit 210, a second input terminal connected to the first input node 21, and an output terminal configured to calculate logical AND of an output signal of the D-FF circuit 210 and the SDA signal and providing an output signal corresponding to the calculation result.

The D-FF circuit 210 includes an input terminal D configured to receive the output signal from the AND circuit 211, a clock input terminal CK configured to receive the signal SA_DLY, and the output terminal Q, and has an initial value of 1.

The D-FF circuit 220 includes an input terminal D configured to receive an output signal from the OR circuit 221, a clock input terminal CK configured to receive a signal obtained by inverting the signal SA_DLY by the inverter 222, and an output terminal Q, and has an initial value of 0.

The OR circuit 221 includes a first input terminal connected to the output terminal Q of the D-FF circuit 220, a second input terminal connected to the first input node 21, and an output terminal configured to calculate logical OR of an output signal of the D-FF circuit 220 and the SDA signal and providing an output signal corresponding to the calculation result.

The AND circuit 25 includes a first input terminal 251 connected to the output terminal of the D-FF circuit 210, a second input terminal 252 connected to the output terminal of the D-FF circuit 220 through the inverter 223, and the output terminal 253. The AND circuit 25 supplies an SDA short-circuit determination signal as a first determination signal including a signal level corresponding to a calculation result of logical AND of respective signals supplied to the first input terminal 251 and the second input terminal 252, from the output terminal 253 to the output node 23.

Here, the AND circuit 211 and the D-FF circuit 210 form a first logic circuit in the SDA short-circuit determination signal generation circuit 20. The OR circuit 221 and the D-FF circuit 220 form a second logic circuit in the SDA short-circuit determination signal generation circuit 20. Here, the output signal of the D-FF circuit 210 corresponds to an output signal of the first logic circuit, and the output signal of the D-FF circuit 220 corresponds to an output signal of the second logic circuit.

In the SDA short-circuit determination signal generation circuit 20, the AND circuit 211 and the D-FF circuit 210 determine that the signal level of the SDA signal is not “1”, that is, “0” when the voltage of the signal SA_DLY which is the SA signal delayed by a predetermined time rises from the voltage Vss to the voltage Vdd, and supply a signal including a signal level corresponding to the determination result to the first input terminal 251 of the AND circuit 25.

In a case in which the calculation result of the AND circuit 211 is “false,” that is, “0”, the D-FF circuit 210 provides an output signal of a signal level “0” because an input signal of the signal level “0” is supplied to the signal input terminal. Once the D-FF circuit 210 outputs an output signal having a signal level of “0”, the output signal of the D-FF circuit 210 is thereafter fixed at the signal level “0”.

In addition, in the SDA short-circuit determination signal generation circuit 20, the OR circuit 221 and the D-FF circuit 220 determine that the signal level of the SDA signal is not “0”, that is, “1” when the voltage of the signal SA_DLY which is the SA signal delayed by a predetermined time falls from the voltage Vdd to the voltage Vss, and supply a signal obtained by inverting, by the inverter 223, a signal including a signal level corresponding to the determination result to the second input terminal 252 of the AND circuit 25.

In a case in which the calculation result of the OR circuit 221 is “true,” that is, “1”, the D-FF circuit 220 provides an output signal of a signal level “1”because an input signal of the signal level “1”is supplied to the input terminal D. Once the D-FF circuit 220 outputs an output signal having a signal level of “1”, the output signal of the D-FF circuit 220 is fixed at the signal level “1”.

The AND circuit 25 provides the SDA short-circuit determination signal including the signal level corresponding to the calculation result of the logical AND of the respective signals supplied to the first input terminal 251 and the second input terminal 252, from the output terminal 253. The output signal of the AND circuit 25 indicates a true/false determination result of determining establishment (true) or non-establishment (false) of a first condition that “the SDA signal is ‘1’ at the rising edge of the signal SA_DLY and the SDA signal is ‘0’ at the falling edge of the signal SA_DLY.” The signal levels “0” and “1”of the output signal of the AND circuit 25 correspond to the non-establishment (false) and the establishment (true) of the first condition, respectively.

The SCL short-circuit determination signal generation circuit 30 includes, for example: a D flip-flop circuit (hereinafter referred to as “D-FF circuit”) 310 configured to operate at a clock rising edge; an AND circuit 311; a D-FF circuit 320; an OR circuit 321; an inverter 322 and an inverter 323; and an AND circuit 35. The SCL short-circuit determination signal generation circuit 30 further includes: a first input node 31 connected to the SCL terminal 13; a second input node 32 connected to the output node of the delay element 16; and an output node 33 connected to an output terminal 353 of the AND circuit 35.

The AND circuit 311 includes a first input terminal connected to an output terminal Q of the D-FF circuit 310, a second input terminal connected to the first input node 31, and an output terminal configured to calculate logical AND of an output signal of the D-FF circuit 310 and the SCL signal and providing an o signal corresponding to the calculation result.

The D-FF circuit 310 includes an input terminal D configured to receive the output signal from the AND circuit 311, a clock input terminal CK configured to receive the signal SA_DLY, and the output terminal Q.

The D-FF circuit 320 includes an input terminal D configured to receive an output signal from the OR circuit 321, a clock input terminal CK configured to receive a signal obtained by inverting the signal SA_DLY by the inverter 322, and an output terminal Q.

The OR circuit 321 includes a first input terminal connected to the output terminal Q of the D-FF circuit 320, a second input terminal connected to the first input node 31, and an output terminal configured to calculate logical OR of an output signal of the D-FF circuit 320 and the SCL signal and providing an output signal corresponding to the calculation result.

The AND circuit 35 includes a first input terminal 351 connected to the output terminal of the D-FF circuit 310, a second input terminal 352 connected to the output terminal of the D-FF circuit 320 through the inverter 323, and the output terminal 353. The AND circuit 35 supplies an SCL short-circuit determination signal as a second determination signal including a signal level corresponding to a calculation result of logical AND of respective signals supplied to the first input terminal 351 and the second input terminal 352, from the output terminal 353 to the output node 33.

Here, the AND circuit 311 and the D-FF circuit 310 form a first logic circuit in the SCL short-circuit determination signal generation circuit 30. The OR circuit 321 and the D-FF circuit 320 form a second logic circuit in the SCL short-circuit determination signal generation circuit 30. Here, the output signal of the D-FF circuit 310 corresponds to an output signal of the first logic circuit, and the output signal of the D-FF circuit 320 corresponds to an output signal of the second logic circuit.

In the SCL short-circuit determination signal generation circuit 30, the AND circuit 311 and the D-FF circuit 310 determine that the signal level of the SCL signal is not “1”, that is, “0” when the voltage of the signal SA_DLY which is the SA signal delayed by a predetermined time rises from the voltage Vss to the voltage Vdd, and supply a signal including a signal level corresponding to the determination result to the first input terminal 351 of the AND circuit 35.

In a case in which the calculation result of the AND circuit 311 is “false,” that is, “0”, the D-FF circuit 310 provides an output signal of a signal level “0” because an input signal of the signal level “0” is supplied to the signal input terminal. After that, the output signal of the D-FF circuit 310 is fixed at the signal level “0”.

In addition, in the SCL short-circuit determination signal generation circuit 30, the OR circuit 321 and the D-FF circuit 320 determine that the signal level of the SCL signal is not “0”, that is, “1” when the voltage of the signal SA_DLY which is the SA signal delayed by a predetermined time falls from the voltage Vdd to the voltage Vss, and supply a signal obtained by inverting, by the inverter 323, a signal including a signal level corresponding to the determination result to the second input terminal 352 of the AND circuit 35.

In a case in which the calculation result of the OR circuit 321 is “true,” that is, “1”, the D-FF circuit 320 provides an output signal of a signal level “1”because an input signal of the signal level “1”is supplied to the input terminal D. After that, the output signal of the D-FF circuit 320 is fixed at the signal level “1”.

The AND circuit 35 provides the SCL short-circuit determination signal including the signal level corresponding to the calculation result of the logical AND of the respective signals supplied to the first input terminal 351 and the second input terminal 352, from the output terminal 353. The output signal of the AND circuit 35 indicates a true/false determination result of determining establishment (true) or non-establishment (false) of a second condition that “the SCL signal is ‘1’ at the rising edge of the signal SA_DLY and the SCL signal is ‘0’ at the falling edge of the signal SA_DLY.” The signal levels “0” and “1”of the output signal of the AND circuit 35 correspond to the non-establishment (false) and the establishment (true) of the second condition, respectively.

Subsequently, an operation of address determination of the address determination circuit 10 is described by taking a case of performing I²C communication as an example.

FIG. 4A is a timing chart for illustrating a case in which the SA terminal 12 is short-circuited to the SCL line (not illustrated), and FIG. 4B is a timing chart for illustrating a case in which the SA terminal 12 is short-circuited to the SDA line (not illustrated).

In the address determination circuit 10, as described above, the SDA short-circuit determination signal generation circuit 20 (see FIG. 2) determines whether the first condition that “the SDA signal is ‘1’ at the rising edge of the signal SA_DLY and the SDA signal is ‘0’ at the falling edge of the signal SA_DLY” is established (true) or not established (false), and the SCL s short-circuit determination signal generation circuit 30 (see FIG. 3) determines whether the second condition that “the SCL signal is ‘1’ at the rising edge of the signal SA_DLY and the SCL signal is ‘0’ at the falling edge of the signal SA_DLY” is established (true) or not established (false).

In a case in which the SA terminal 12 is short-circuited to the SCL line (not illustrated) (see FIG. 4A), with reference to FIG. 4A, the SCL signal is “1” at the rising edge of the signal SA_DLY and “0” at the falling edge of the signal SA_DLY in any pulse. Meanwhile, based on the operation of the SDA short-circuit determination signal generation circuit 20 described above, the SDA signal is “0” at the rising edge of the second pulse (indicated by the downward broken-line arrow) of the signal SA_DLY, and is “0” at the falling edge of the signal SA_DLY. Accordingly, the fourth proposition is established, and it is determined that the address selection signal is not the SDA signal. Further, in a case in which the SA terminal 12 is short-circuited to the VDD line or the VSS line, the address selection signal is constantly “1”or “0” and the signal level does not fluctuate. Thus, in a case in which the signal level of the signal SA_DLY fluctuates, it is determined that the address selection signal is the remaining SCL signal.

In a case in which the SA terminal 12 is short-circuited to the SDA line (not illustrated) (see FIG. 4B), with reference to FIG. 4B, the SDA signal is “1” at the rising edge of the signal SA_DLY and “0” at the falling edge of the signal SA_DLY in any pulse. Meanwhile, based on the operation of the SCL short-circuit determination signal generation circuit 30 described above, the SCL signal is “0” at the rising edge of the pulse (indicated by the downward broken-line arrow) of the signal SA_DLY, and is “0” at the falling edge of the signal SA_DLY. Accordingly, the third proposition is established, and it is determined that the address selection signal is not the SCL signal. Further, in a case in which the SA terminal 12 is short-circuited to the VDD line or the VSS line, the address selection signal is constantly “1”or “0” and the signal level does not fluctuate. Thus, in a case in which the signal level of the signal SA_DLY fluctuates, it is determined that the address Selection signal is the remaining SDA signal.

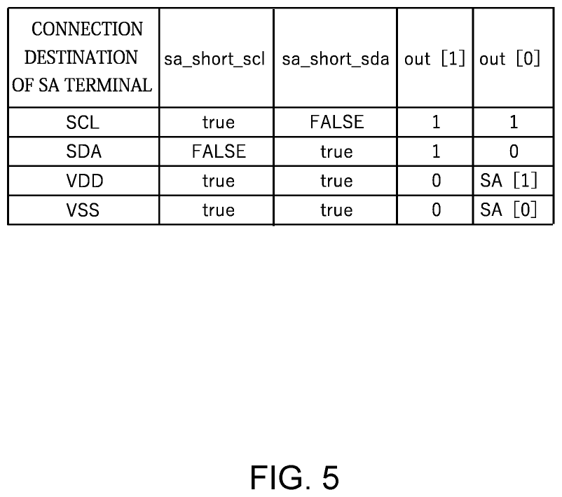

FIG. 5 is a truth value table for illustrating the operation of the SA terminal short-circuit determination circuit 40 included in the address determination circuit 10. In FIG. 5, the SDA short-circuit determination signal and the SCL short-circuit determination signal are illustrated as “sa_short_sda” and “sa_short_scl,” respectively, and a determination location serving as a basis for determining the short-circuit counterpart (connection destination) of the SA terminal 12 is written in uppercase letters.

The SA terminal short-circuit determination circuit 40 determines four types of short-circuit counterparts of the SA terminal 12 based on the SDA short-circuit determination signal (sa_short_sda) from the SDA short-circuit determination signal generation circuit 20 supplied to the first input node, the address selection signal from the SA terminal 12 supplied to the second input node, and the SCL short-circuit determination signal (sa_short_scl) from the SCL short-circuit determination signal generation circuit 30 supplied to the third input node.

Specifically, the SA terminal short-circuit determination circuit 40 determines that the SA terminal is not short-circuited to the SDA line, that is, the SA terminal is short-circuited to the SCL line based on a determination result “FALSE” of the first condition indicated by the SDA short-circuit determination signal (sa_short_sda). In addition, the SA terminal short-circuit determination circuit 40 determines that the SA terminal is not short-circuited to the SCL line, that is, the SA terminal is short-circuited to the SDA line based on a determination result “FALSE” of the second condition indicated by the SCL short-circuit determination signal (sa_short_scl).

In a case in which the determination result of the first condition is “true” and the determination result of the second condition is “true,” the SA terminal short-circuit determination circuit 40 cannot completely make a determination only with the SDA short-circuit determination signal (sa_short_sda) and the SCL short-circuit determination signal (sa_short_scl). However, when whether the voltage of the SA terminal 12 is the voltage Vdd or the voltage Vss is known, it is possible to determine whether the SA terminal is short-circuited to the VDD line or short-circuited to the VSS line, because it is clear that the short-circuit counterpart of the SA terminal 12 is not the SDA line and not the SCL line.

Accordingly, the SA terminal short-circuit determination circuit 40 determines that the SA terminal is short-circuited to the VDD line when the voltage of the SA terminal 12 is at the high level corresponding to the voltage Vdd, and determines that the SA terminal is short-circuited to the VSS line when the voltage of the SA terminal 12 is at the low level corresponding to the voltage Vss. The SA terminal short-circuit determination circuit 40 provides a 2-bit signal (00b, 01b, 10b, or 11b) corresponding to the above-mentioned determination result from the output terminal 14 to the outside. In the example illustrated in FIGS. 5, 00b corresponds to the VSS line, 01b corresponds to the VDD line, 10b corresponds to the SDA line, and 11b corresponds to the SCL line.

Next, the accuracy of the address determination of the address determination circuit according to the embodiment is described by giving an example of the related-art address determination circuit as a reference example.

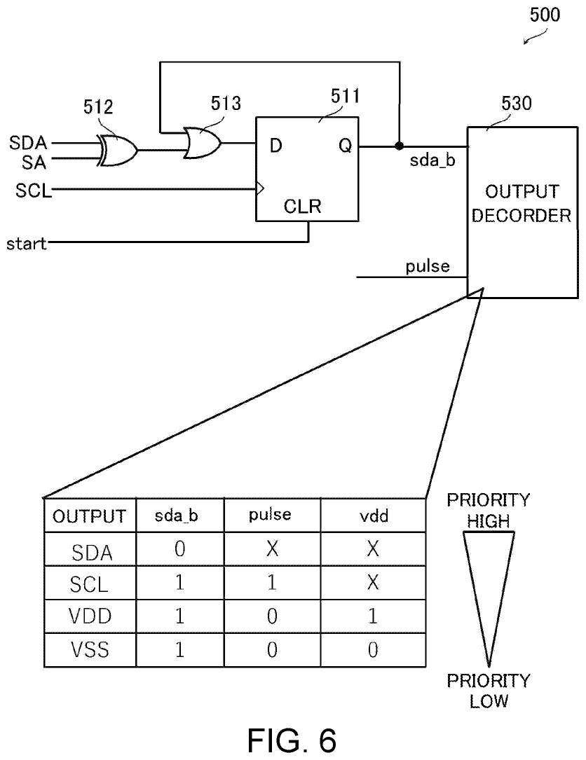

FIG. 6 is a schematic diagram for illustrating a configuration example of an address determination circuit 500 which is the t address determination circuit according to the reference example.

The address determination circuit 500 is a circuit corresponding to FIG. 4A to FIG. 4C as described in Japanese Patent Application Laid-open No. 2010-212989. The address determination circuit 500 includes an EXOR circuit 512, an OR circuit 513, a D-FF circuit 511, and an output decoder 530. The EXOR circuit 512 receives the SDA signal and the SA signal, calculates an exclusive OR thereof, and supplies the result to the OR circuit 513. The OR circuit 513 receives the output signal of the D-FF circuit 511 and the output signal of the EXOR circuit 512, calculates logical OR thereof, and supplies the result to the D-FF circuit 511.

In the D-FF circuit 511, the output signal of the OR circuit 513 is supplied to an input terminal D, and the SCL signal is supplied to a clock input terminal as a clock signal. The D-FF circuit 511 is initialized (cleared) upon receiving a start signal. Further, in the address determination circuit 500, preprocessing configured to shift the timing forward or backward with respect to the SA signal is performed and the signal is supplied to the D-FF circuit 511, from the viewpoint of ensuring the setup/hold time of the D-FF circuit 511.

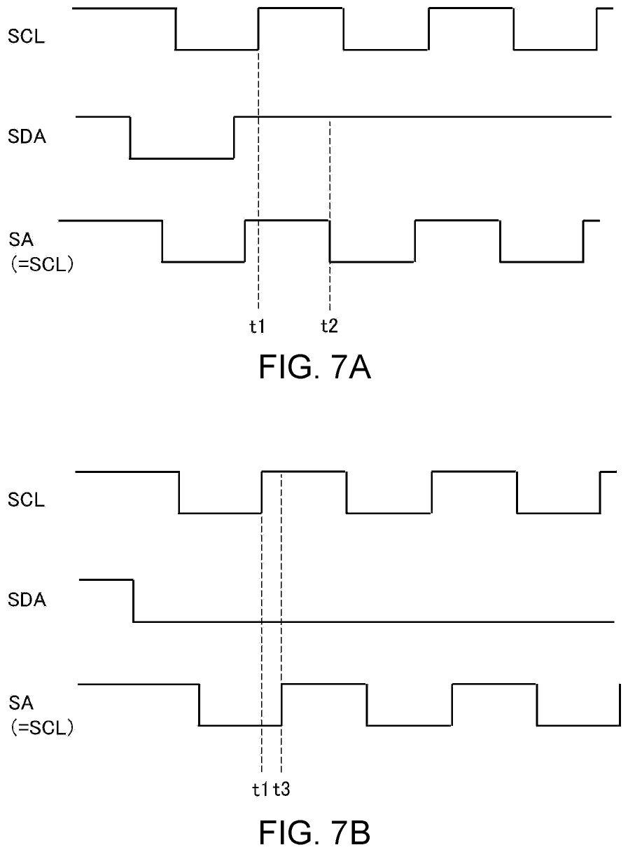

FIG. 7A and FIG. 7B are examples in a case in which data transmission is performed in accordance with an I²C communication protocol, and are timing charts respectively illustrating a first example and a second example of erroneous address determination of the address determination circuit 500.

FIG. 7A illustrates, in order from the top, a waveform of the SCL signal, a waveform of the SDA signal, and a waveform of the SA signal in a case in which the SA signal is the SCL signal and the timing is slightly advanced with respect to the SCL signal and the SDA signal. Further, in each signal waveform, a higher signal level is “1”, and a lower signal level is “0”.

The SDA signal illustrated in FIG. 7A shifts to a start condition, and then transitions from “0” to “1” and thereafter maintains “1”. With reference to the timing chart illustrated in FIG. 7A, at a time t1 which is a time of a first rising edge of the SCL signal after the start condition, the SDA signal is “1” and the SA signal is “1”. When the address determination circuit 500 receives the SDA signal of “1” and the SA signal of “1”, the output signal of the EXOR circuit 512 becomes “0”, the output signal of the OR circuit 513 becomes “0”, and an output signal sda_b of the D-FF circuit 511 becomes “0”.

In this case, the output decoder 530 determines that the highest priority is to be given (the top in the drawing), and determines that the short-circuit counterpart of the SA terminal is the SDA line. As described above, the first example illustrated in FIG. 7A is a case in which the SA signal is the SCL signal, but the address determination circuit 500 erroneously determines that this is a case in which the SA signal is the SDA signal.

Meanwhile, the address determination circuit 10 captures the SDA signal of “1” at the falling edge of the SA signal at a time t2 and determines that the first condition “the SDA signal is ‘1’ at the rising edge of the signal SA_DLY and the SDA signal is ‘0’ at the falling edge of the signal SA_DLY” is not established. Thus, the address determination circuit 10 determines that the SA terminal 12 is short-circuited to the SCL line based on the fact that the first condition is FALSE. That is, the address determination circuit 10 does not make an erroneous determination like the address determination circuit 500 even when transitioning in accordance with the timing illustrated in FIG. 7A.

FIG. 7B illustrates, in order from the top, a waveform of the SCL signal, a waveform of the SDA signal, and a waveform of the SA signal in a case in which the SA signal is the SCL signal and the timing is slightly delayed with respect to the SCL signal and the SDA signal. Further, in each signal waveform, a higher signal level is “1”, and a lower signal level is “0”.

The SDA signal illustrated in FIG. 7B shifts to a start condition, and then maintains “0”. According to the timing chart illustrated in FIG. 7B, at the time t1 which is a time of a first rising edge of the SCL signal after the start condition, the SDA signal is “0” and the SA signal is “0”. When the address determination circuit 500 receives the SDA signal of “0” and the SA signal of “0”, the output signal of the EXOR circuit 512 becomes “0”, the output signal of the OR circuit 513 becomes “0”, and the output signal sda_b of the D-FF circuit 511 becomes “0”.

At the timing illustrated in FIG. 7B as well, similarly to the timing illustrated in FIG. 7A described above, the output decoder 530 determines that the highest priority is to be given (the top in the drawing), and erroneously determines that the short-circuit counterpart of the SA terminal is the SDA line.

Meanwhile, the address determination circuit 10 captures the SDA signal of “0” at the rising edge of the SA signal at a time t3 and determines that the first condition “the SDA signal is ‘1’ at the rising edge of the signal SA_DLY and the SDA signal is ‘0’ at the falling edge of the signal SA_DLY” is not established. Thus, the address determination circuit 10 determines that the SA terminal 12 is short-circuited to the SCL line based on the fact that the first condition is FALSE. That is, the address determination circuit 10 does not make an erroneous determination like the address determination circuit 500 even when transitioning in accordance with the timing illustrated in FIG. 7B.

Subsequently, a countermeasure for avoiding a metastable state in the address determination circuit 10 is briefly described. In the address determination circuit 10, when the SDA short-circuit determination signal or the SCL short-circuit determination signal is erroneously determined as “FALSE” due to occurrence of a metastable state, the short-circuit counterpart of the SA terminal 12 is erroneously determined, because the four types of short-circuit counterparts of the SA terminal 12 are determined based on the true/false determination of the SDA short-circuit determination signal and the SCL short-circuit determination signal. However, in the address determination circuit 10, the metastable state is avoided, or a countermeasure is provided so as not to finally make an erroneous determination even when the metastable state occurs. The specific countermeasure is as follows.

In a case in which the SA terminal 12 is short-circuited to the VDD line or the VSS line, an erroneous determination of short-circuit of the SA terminal 12 due to occurrence of a metastable state does not possibly occur because the SDA short-circuit determination signal or the SCL short-circuit determination signal remains at an initial value. The metastable state occurs in a case in which the setup/hold time of the FF circuit is insufficient with respect to the rising edge or falling edge of the signal waveform. However, in the address determination circuit 10, to prevent the setup/hold time of the FF circuit from becoming insufficient, for example, a noise filter is inserted into each of an SDA terminal 11 and an SCL terminal 13, and/or a signal SA_DLY obtained by delaying an SA signal is supplied to D-FF circuits 210, 220, 310, and 320. Accordingly, the SDA short-circuit determination signal generation circuit 20 and the SCL short-circuit determination signal generation circuit 30 are configured to prevent the occurrence of metastability.

The present invention is not limited to the above-mentioned at least one embodiment as it is, and can be embodied in various modes other than the above-mentioned at least one embodiment at an execution stage, and various omissions, additions, replacements, or changes can be made without departing from the gist of the invention. Subsequently, among several modes that can be modified, several modification examples of the address determination circuit and the semiconductor device are described.

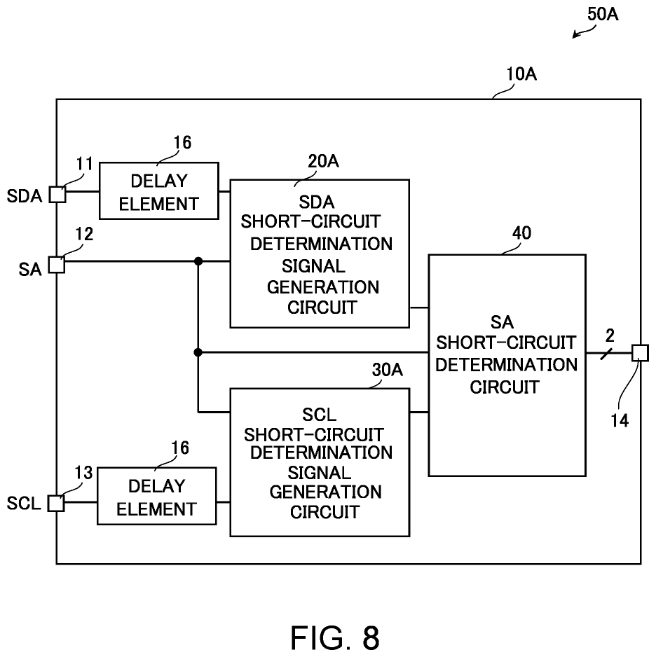

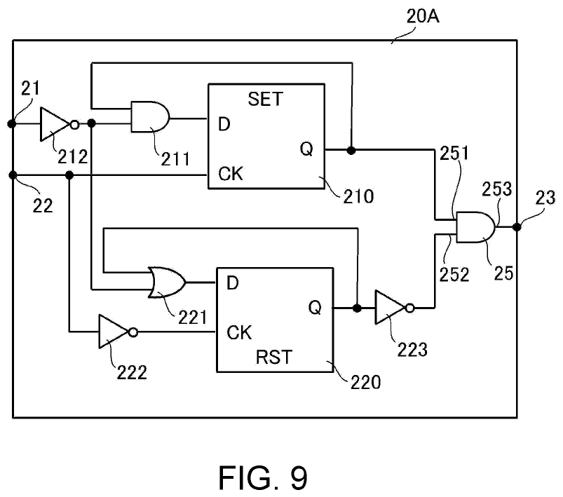

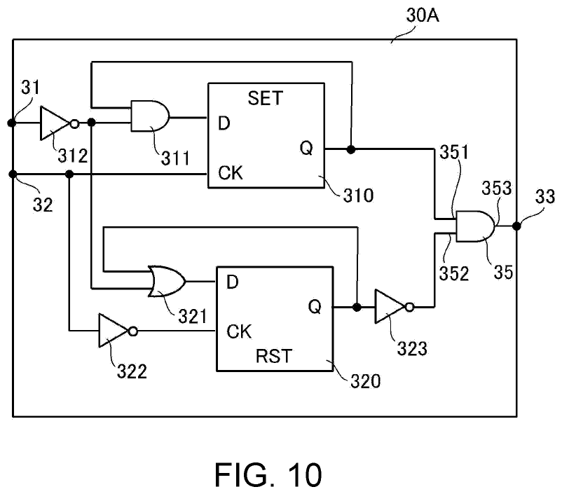

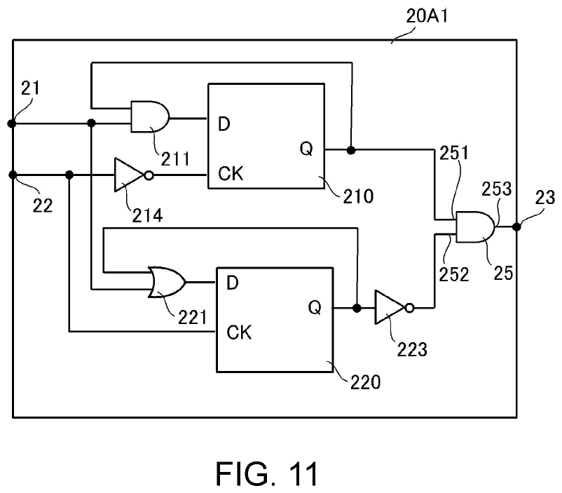

FIG. 8 is a schematic diagram for illustrating configurations of an address determination circuit 10A and a semiconductor device 50A which are a first modification example (second configuration example) of the address determination circuit and the semiconductor device according to the embodiment. In addition, FIG. 9 and FIG. 10 are circuit diagrams respectively illustrating a first modification example (second configuration example) the SDA short-circuit determination signal generation circuit and a first modification example (second configuration example) of the SCL short-circuit determination signal generation circuit in the address determination circuit according to the embodiment. FIG. 11 is a circuit diagram for illustrating a second modification example (third configuration example) of the SDA short-circuit determination signal generation circuit in the address determination circuit according to the embodiment.

The address determination circuit 10A is configured to generate the SDA short-circuit determination signal and the SCL short-circuit determination signal through use of the SA signal advanced by a predetermined time with respect to the SDA signal and the SCL signal, as compared to the address determination circuit 10. That is, in the address determination circuit 10A, a temporal relationship (advance and delay) between the SDA signal and the SA signal and a temporal relationship (advance and delay) between the SCL signal and the SA signal are reversed as compared to the address determination circuit 10.

The address determination circuit 10A and the semiconductor device 50A differ from the address determination circuit 10 in that an SDA short-circuit determination signal generation circuit 20A is provided in place of the SDA short-circuit determination signal generation circuit 20, an SCL short-circuit determination signal generation circuit 30A is provided in place of the SCL short-circuit determination signal generation circuit 30, and a position at which the delay element 16 is connected is different, but are substantially the same in other respects. In the address determination circuit 10A, the delay element 16 is connected between the SDA terminal 11 and the SDA short-circuit determination signal generation circuit 20A, and between the SCL terminal 13 and the SCL short-circuit determination signal generation circuit 30A, while the delay element 16 is not connected between the SA terminal 12 and each of the SDA short-circuit determination signal generation circuit 20A and the SCL short-circuit determination signal generation circuit 30A.

The SDA short-circuit determination signal generation circuit 20A differs from the SDA short-circuit determination signal generation circuit 20 in that an inverter 212 is connected between the first input node 21 and each of the second input terminal of the AND circuit 211 and the second input terminal of the OR circuit 221, but is substantially the same in other respects. In addition, the SCL short-circuit determination signal generation circuit 30A differs from the SCL short-circuit determination signal generation circuit 30 in that an inverter 312 is connected between the first input node 31 and each of the second input terminal of the AND circuit 311 and the second input terminal of the OR circuit 321, but is substantially the same in other respects.

The configuration further includes the inverter 212 and the inverter 312 because the signal levels in the above-mentioned first proposition and second proposition are reversed in a case in which a signal SA_FWD which is the SA signal advanced by a predetermined time with respect to the SDA signal and the SCL signal is used. Specifically, in the address determination circuit 10A, the following proposition 1A and proposition 2A are both true:
Proposition 1A “In a case in which the address selection signal is the SCL signal, the SCL signal is ‘0’ at a rising edge of the signal SA_FWD, and the SCL signal is ‘1’ at a falling edge of the signal SA FWD.”; and
Proposition 2A “In a case in which the address selection signal is the SDA signal, the SDA signal is ‘0’ at the rising edge of the signal SA_FWD, and the SDA signal is ‘1’ at the falling edge of the signal SA FWD.”

Accordingly, a proposition 3A which is a contrapositive of the proposition 1A and a proposition 4A which is a contrapositive of the proposition 2A are as follows:
Proposition 3A “Unless the SCL signal is ‘0’ at the rising edge of the signal SA_FWD and the SCL signal is ‘1’ at the falling edge of the signal SA_FWD, the address selection signal is not the SCL signal.”; and
Proposition 4A “Unless the SDA signal is ‘0’ at the rising edge of the signal SA_FWD and the SDA signal is ‘1’ at the falling edge of the signal SA_FWD, the address selection signal is not the SDA signal.”

Note that, although the SDA short-circuit determination signal generation circuit 20A illustrated in FIG. 9 is configured such that an inverter 212 is connected between a first input node 21 and both a second input terminal of an AND circuit 211 and a second input terminal of an OR circuit 221, the SDA short-circuit determination signal generation circuit 20 (see FIG. 2) may be configured such that the inverter 212 is connected between a second input node 22 and both a clock input terminal CK of a D-FF circuit 210 and an input terminal of an inverter 222. Furthermore, as in an SDA short-circuit determination signal generation circuit 20Al illustrated in FIG. 11, a configuration may be adopted in which the series connection of the inverter 212 and the inverter 222 is simplified, and instead of the inverter 212, an inverter 214 is connected between a connection point of the second input node 22 and a clock input terminal CK of a D-FF circuit 220, and the clock input terminal CK of the D-FF circuit 210. Although illustration of a second modification (a third configuration example) of an SCL short-circuit determination signal generation circuit 30A is omitted, the SCL short-circuit determination signal generation circuit 30A may also be modified in the same manner as the SDA short-circuit determination signal generation circuit 20A.

Subsequently, a second modification example (third configuration example) is described.

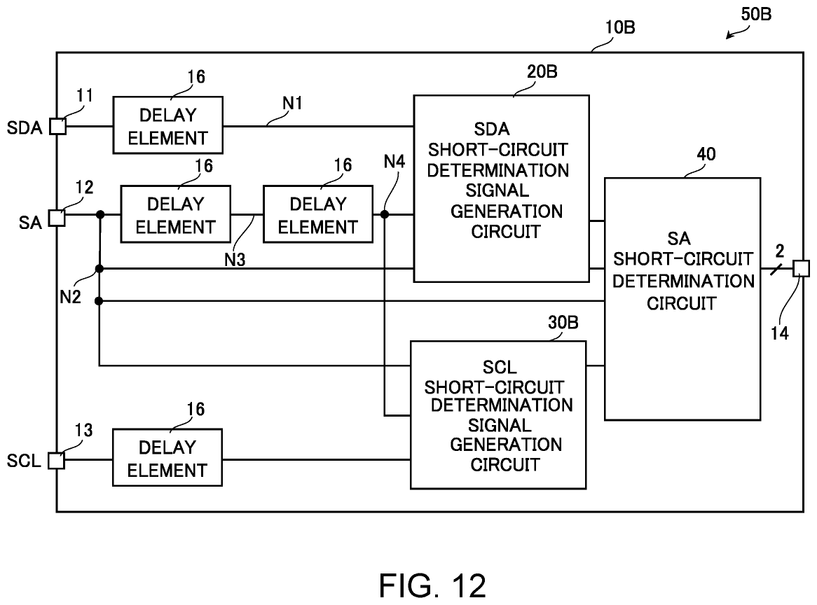

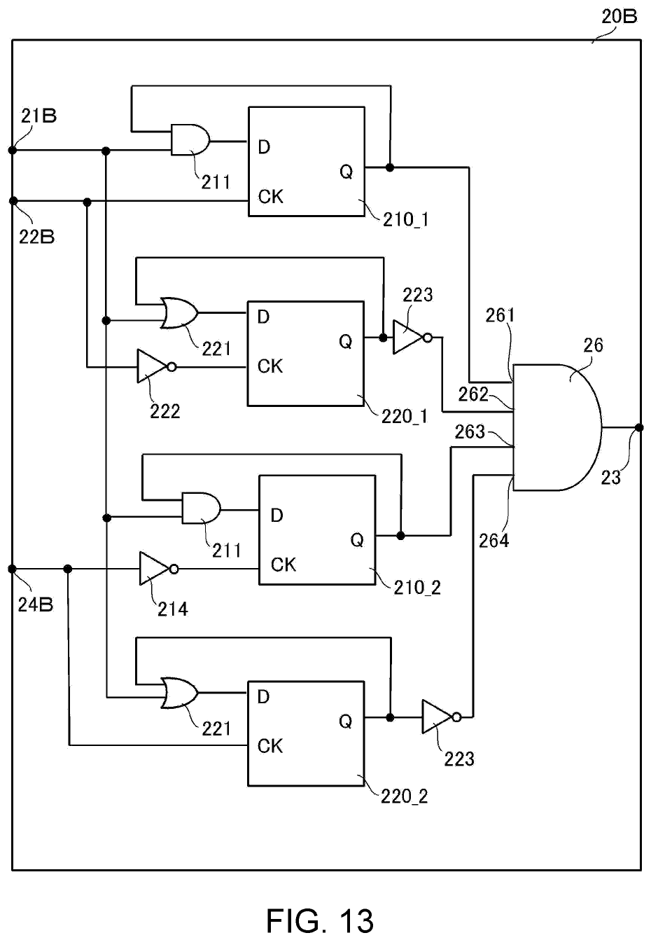

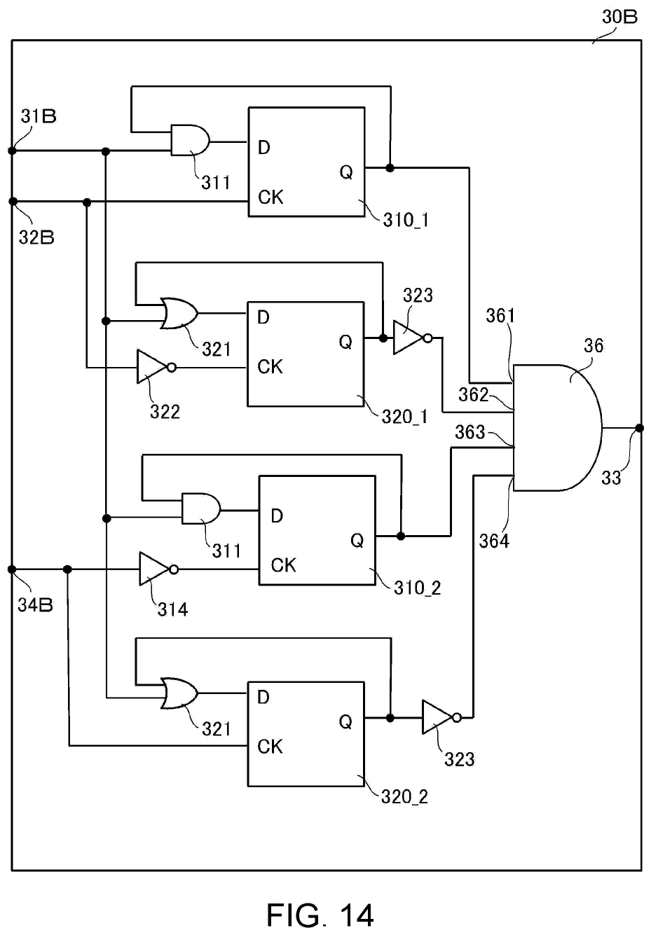

FIG. 12 is a schematic diagram for illustrating configurations of an address determination circuit 10B and a semiconductor device 50B which are the second modification example (third configuration example) of the address determination circuit and the semiconductor device according to the embodiment. FIG. 13 and FIG. 14 are circuit diagrams respectively illustrating configurations of an SDA short-circuit determination signal generation circuit 20B and an SCL short-circuit determination signal generation circuit 30B in the third configuration example.

The address determination circuit 10B differs from the address determination circuit 10 in that a plurality of delay elements 16 are provided, the SDA short-circuit determination signal generation circuit 20B is provided in place of the SDA short-circuit determination signal generation circuit 20, and the SCL short-circuit determination signal generation circuit 30B is provided, but is substantially the same in other respects. Accordingly, in describing the address determination circuit 10B and the semiconductor device 50B, overlapping components are denoted by the same reference numerals, and description thereof is omitted.

In the address determination circuit 10B, at least one delay element 16 is connected in series to each of the SDA terminal 11, the SA terminal 12, and the SCL terminal 13. More specifically, one delay element 16 is connected between the SDA terminal 11 and an input side of the SDA short-circuit determination signal generation circuit 20B, two delay elements 16 connected in series are connected between the SA terminal 12 and each of the input side of the SDA short-circuit determination signal generation circuit 20B and an input side of the SCL short-circuit determination signal generation circuit 30B, and one delay element 16 is connected between the SCL terminal 13 and the input side of the SCL short-circuit determination signal generation circuit 30B.

In the address determination circuit 10B, a signal obtained by delaying the signal supplied from the SDA terminal 11 by one stage is supplied to a node N1. The signal (without delay) supplied from the SA terminal 12 is supplied to a node N2. A signal obtained by delaying the signal supplied from the SA terminal 12 by one stage is supplied to a node N3. A signal obtained by delaying the signal supplied from the SA terminal 12 by two stages is supplied to a node N4. A signal obtained by delaying the signal supplied from the SCL terminal 13 by one stage is supplied to a node N5.

To the SDA short-circuit determination signal generation circuit 20B, the signal obtained by delaying the signal supplied from the SDA terminal 11 by one stage, the signal (without delay) supplied from the SA terminal 12, and the signal obtained by delaying the signal supplied from the SA terminal 12 by two stages are supplied. To the SCL short-circuit determination signal generation circuit 30B, the signal obtained by delaying the signal supplied from the SCL terminal 13 by one stage, the signal (without delay) supplied from the SA terminal 12, and the signal obtained by delaying the signal supplied from the SA terminal 12 by two stages are supplied.

The SDA short-circuit determination signal generation circuit 20B includes four D-FF circuits 210_1, 220_1, 210_2, and 220_2, four inverters 214, 222 and 223, and an AND circuit 26 configured to perform logical AND calculation of signals respectively supplied from four input terminals 261 to 264. Equivalently, the SDA short-circuit determination signal generation circuit 20B is a logic circuit that outputs a logical AND of the respective output signals of two SDA short-circuit determination signal generation circuits 20 and 20A1 (see FIGS. 2 and 11).

The SDA short-circuit determination signal generation circuit 20B further includes: a first input node 21B having an input end connected to an output end of the delay element 16 connected to the SDA terminal 11 to form the node N1; a second input node 22B having an input end connected to an output end of the two delay elements 16 connected in series to the SA terminal 12 to form the node N4; a third input node 24B directly connected to the SA terminal 12; and an output node 23 connected to an output terminal of the AND circuit 26. The inverter 214 is connected between the third input node 24B and a clock input terminal CK of the D-FF circuit 210_2.

The SCL short-circuit determination signal generation circuit 30B has the same configuration as that of the SDA short-circuit determination signal generation circuit 20B. The SCL short-circuit determination signal generation circuit 30B includes four D-FF circuits 310_1, 320_1, 310_2, and 320_2, four inverters 314, 322, and 323, and an AND circuit 36 configured to perform logical AND calculation of signals respectively supplied from four input terminals 361 to 364. Equivalently, the SCL short-circuit determination signal generation circuit 30B is a logic circuit configured to output a logical AND of respective output signals of two SCL short circuit determination signal generation circuits 30 and a modification of the SCL short-circuit determination signal generation circuit 30A (corresponding to the SDA short-circuit determination signal generation circuit 20A1; see FIG. 11).

The SCL short-circuit determination signal generation circuit 30B further includes: a first input node 31B connected to the SCL terminal 13 through the delay element 16; a second input node 32B connected to the SA terminal 12 through the two delay elements 16; a third input node 34B directly connected to the SA terminal 12; and an output node 33 connected to an output terminal of the AND circuit 36. The inverter 314 is connected between the third input node 34B and a clock input terminal CK of the D-FF circuit 310_2.

Operations of the SDA short-circuit determination signal generation circuit 20B, the SCL short-circuit determination signal generation circuit 30B, and the SA terminal short-circuit determination circuit 40 in the operation of the address determination circuit 10B are described.

The SDA short-circuit determination signal generation circuit 20B uses the timing of the SDA signal as a reference, and determines the signal level not only at a rising edge and a falling edge of the SA signal delayed by a predetermined time with respect to that timing, but also at a rising edge and a falling edge of the SA signal advanced by a predetermined time with respect to the timing of the SDA signal. Accordingly, accuracy of address determination can be further improved because true or false of the “first condition” is determined at a larger number of observation points than those of the SDA short-circuit determination signal generation circuit 20.

The SCL short-circuit determination signal generation circuit 30B uses the timing of the SCL signal as a reference, and determines the signal level not only at the rising edge and the falling edge of the SA signal delayed by a predetermined time with respect to that timing, but also at the rising edge and the falling edge of the SA signal advanced by a predetermined time with respect to the timing of the SCL signal. Accordingly, accuracy of address determination can be further improved because true or false of the “second condition” is determined at a larger number of observation points than those of the SCL short-circuit determination signal generation circuit 30.

The SA terminal short-circuit determination circuit 40 in the address determination circuit 10B is substantially the same in operation as the SA terminal short-circuit determination circuit 40 in the address determination circuit 10 or the address determination circuit 10A. That is, the SA terminal short-circuit determination circuit 40 determines the connection destination of the SA terminal 12 in accordance with a logic based on the truth value table illustrated as an example in FIG. 5. However, in the address determination circuit 10B, accuracy of address determination can be further improved because the SDA short-circuit determination signal and the SCL short-circuit determination signal obtained by determining conditions at a larger number of observation points than those of the address determination circuit 10 or the address determination circuit 10A are applied.

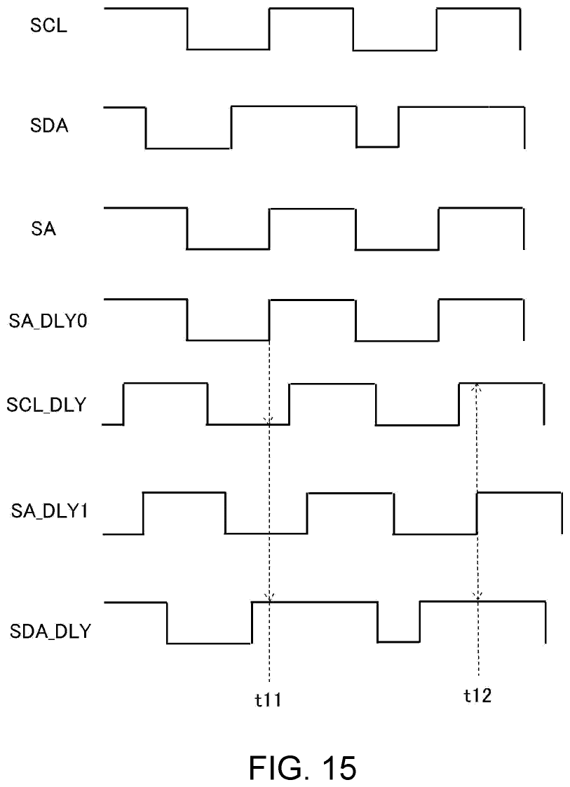

FIG. 15 is a timing chart for illustrating a case in which the SA terminal 12 is short-circuited to the SCL line in the address determination circuit 10B.

FIG. 15 illustrates, in order from the top, the SCL signal, the SDA signal, the SA signal, a signal SA_DLYO (=SA signal) which is the SA signal without delay with respect to the SA signal, a signal SCL_DLY which is the SCL signal delayed by one stage, a signal SA_DLY2 which is the SA signal delayed by two stages, and a signal SDA DLY which is the SDA signal delayed by one stage. The SDA signal illustrated as an example in FIG. 15 changes to fall simultaneously with or slightly later than the falling edge of the SCL signal (level change of the SDA signal is prohibited during a period in which the SCL signal is at an H level).

The address determination circuit 10B determines the signal SCL_DLY and the signal SDA_DLY at two observation points (times t11 and t12) of the signal SA_DLY0 (without delay) advanced by one stage and the signal SA_DLY2 (delayed by two stages) delayed by one stage with respect to the signal SCL_DLY and the signal SDA_DLY. With two observation points being provided, even in a special case in which an SDA short-circuit determination signal (sa_short_sda) fails to detect that a condition is not satisfied (false) at one observation point (time t11) (and thus “true” is erroneously output), correct detection can be performed at the other observation point (time t12).

As described above, according to the at least one aspect of the present invention, the address determination circuits 10, 10A, and 10B and the semiconductor devices 50, 50A, and 50B in which four addresses are set for one SA terminal can be configured with higher accuracy of address determination with a simple circuit configuration. According to the at least one aspect of the present invention, accuracy of address determination can be improved because the address is determined based on the SA signal, and the SDA short-circuit determination signal and the SCL short-circuit determination signal generated based on at least one signal shifted by a predetermined time, for example, delayed by a predetermined time, with respect to the SA signal as a reference.

In addition, the address determination circuits 10, 10A, and 10B described above are examples in which one SA terminal 12 is provided, but a plurality of SA terminals 12 may be provided. In the address determination circuits 10, 10A, and 10B each including a plurality of (“k”) SA terminals 12, the set addresses can be determined up to 4^{k} set addresses. In addition, although the case in which the second input terminal of the SA terminal short-circuit determination circuit 40 is connected to the SA terminal 12 has been described, the second input terminal of the SA terminal short-circuit determination circuit 40 may be connected to the output end of the delay element 16 (the node N3 or the node N4 in the address determination circuit 10B) instead of the SA terminal 12.

Note that, in the SDA short-circuit determination signal generation circuit 20B (see FIG. 13), a portion corresponding to the SDA short-circuit determination signal generation circuit 20A1 (see FIG. 11) may be configured as the SDA short-circuit determination signal generation circuit 20A (see FIG. 9). The SCL short-circuit determination signal generation circuit 30B may be modified in the same manner as the SDA short-circuit determination signal generation circuit 20B. The at least one embodiment and modifications thereof described above are encompassed in the scope and the gist of the invention, and are encompassed in the invention defined in the appended claims and equivalents thereof.

### EXPLANATION OF REFERENCE NUMERALS

10, 10A, 10B address determination circuit
20, 20A, 20B SDA short-circuit determination signal generation circuit
30, 30A, 30B SCL short-circuit determination signal generation circuit
40 SA terminal short-circuit determination circuit (address selection signal determination circuit)
50, 50A, 50B semiconductor device

1. An address determination circuit which is a circuit configured to determine an address of serial communication that transmits and receives a transmission start signal, a data signal, and a transmission end signal through a communication line, the address determination circuit comprising:
an address selection signal input terminal;
a serial data input terminal;
a serial clock input terminal; and
an address selection signal determination circuit configured to:
receive a first determination signal based on a result of latching a level of a serial data signal supplied to the serial data input terminal at a first edge timing at which an address selection signal supplied to the address selection signal input terminal transitions from a first power supply voltage to a second power supply voltage, and at a second edge timing at which the address selection signal transitions from the second power supply voltage to the first power supply voltage; and
receive a second determination signal based on a result of latching a level of a serial clock signal supplied to the serial clock input terminal at the first edge timing and at the second edge timing,
wherein the address selection signal determination circuit is configured to:
determine that the address selection signal is the serial clock signal in a case in which the first determination signal is at a signal level corresponding to false;
determine that the address selection signal is the serial data signal in a case in which the second determination signal is at a signal level corresponding to false; and
determine that the address selection signal is one of the first power supply voltage or the second power supply voltage based on a voltage of the address selection signal in a case in which both of the first determination signal and the second determination signal are at signal levels corresponding to true.

2. The address determination circuit according to claim 1, further comprising at least one delay element configured to delay at least one of the serial data signal, the serial clock signal, or the address selection signal,
wherein the first edge timing and the second edge timing include a plurality of signal edges of different delay times generated by the at least one delay element.

3. The address determination circuit according to claim 1, further comprising:
a first signal generation circuit configured to generate the first determination signal; and
a second signal generation circuit configured to generate the second determination signal,
wherein the first signal generation circuit and the second signal generation circuit each include:
a plurality of flip-flop circuits configured to latch an input signal in response to at least one of a rising edge or a falling edge of the address selection signal; and
a logic gate configured to calculate logical AND of output signals of the plurality of flip-flop circuits.

4. The address determination circuit according to claim 2, further comprising:
a first signal generation circuit configured to generate the first determination signal; and
a second signal generation circuit configured to generate the second determination signal,
wherein the first signal generation circuit and the second signal generation circuit each include:
a plurality of flip-flop circuits configured to latch an input signal in response to at least one of a rising edge or a falling edge of the address selection signal; and
a logic gate configured to calculate logical AND of output signals of the plurality of flip-flop circuits.

5. A semiconductor device, comprising the address determination circuit of claim 1.
